(19) United States
(12) Patent Application Publication
(10) Pub. No.: US 2012/0153346 A1
(43) Pub. Date: Jun. 21, 2012

(54) METHOD FOR PRODUCING RECYCLED SUBSTRATE, RECYCLED SUBSTRATE, NITRIDE SEMICONDUCTOR ELEMENT, AND LAMP

(75) Inventor: Katsuki Kusunoki, Ichihara-shi (JP)

(73) Assignee: SHOWA DENKO K.K., Minato-ku, Tokyo (JP)

(21) Appl. No.: 13/393,150

(22) PCT Filed: Sep. 7, 2010
(86) PCT No.: PCT/JP2010/065338

§ 371 Date: Feb. 28, 2012

(30) Foreign Application Priority Data
Sep. 18, 2009 (JP) 2009-217947

(51) Int. Cl. H01L 33/32; H01L 29/20; H01L 21/263

(52) U.S. Cl. 257/103; 438/4; 257/615; 257/E33.025; 257/E29.089; 257/E21.333

(57) ABSTRACT

A laminated semiconductor wafer (10) to be processed is provided with a substrate (110) and a laminated semiconductor layer (100) formed on the substrate (110). The laminated semiconductor wafer (10) is heated to a temperature above the sublimation point of the laminated semiconductor layer (100) and under the melting point of the substrate (110). As a result, in the laminated semiconductor wafer (10), the laminated semiconductor layer (100) sublimes, and the laminated semiconductor layer (100) is eliminated from the substrate (110). In this way, the laminated semiconductor layer is eliminated from the laminated semiconductor wafer while suppressing damage to the substrate.

### TECHNICAL FIELD

The present invention relates to, for example, a method for producing a recycled substrate by eliminating a laminated semiconductor layer from a laminated semiconductor wafer.

### BACKGROUND ART

There is a technique to recycle a substrate by eliminating a laminated semiconductor layer from a laminated semiconductor wafer that has the laminated semiconductor layer formed on a substrate, for the purpose of reusing the substrate. For example, Patent Literature 1 discloses that thin films formed on a silicon wafer by means of CVD or PVD are eliminated by blowing alumina or silicon carbide, as a polishing agent, in the form of a fluid mixed with compressed air by use of a sandblasting apparatus.

### CITATION LIST

### Patent Literature

Patent Literature 1: Japanese Patent Application Laid-Open Publication No. 2001-237201

### SUMMARY OF INVENTION

### Technical Problem

When a laminated semiconductor layer is eliminated from a laminated semiconductor wafer, it is required not to damage the substrate. For example, if the substrate is damaged, an additional step, such as polishing the substrate, is required in order to remove the damaged portion. Further, if the degree of damage of the substrate is large, the substrate may not be used as a recycled substrate.

An object of the present invention is to eliminate a laminated semiconductor layer from a laminated semiconductor wafer while suppressing damage to the substrate.

### Solution to Problem

In order to attain the above object, a method for producing a recycled substrate to which the present invention is applied is a method for producing a recycled substrate by removing a laminated semiconductor layer from a laminated semiconductor wafer that has the laminated semiconductor layer formed on a substrate, the method including: a first step of setting, in a heating apparatus, the laminated semiconductor wafer that has the laminated semiconductor layer formed on the substrate; and a second step of heating the laminated semiconductor wafer to a temperature above the sublimation point of the laminated semiconductor layer and under the melting point of the substrate.

In such a method for producing a recycled substrate, in the second step, the laminated semiconductor wafer may be heated by decreasing pressure in the heating apparatus below atmospheric pressure. In the second step, the temperature may be maintained while the laminated semiconductor layer is eliminated from the laminated semiconductor wafer.

The laminated semiconductor layer of the laminated semiconductor wafer may include a group III nitride compound semiconductor. Further, the substrate of the laminated semiconductor wafer may be a sapphire substrate. In the second step, the laminated semiconductor wafer may be heated to a temperature between 800 degrees C. and 2000 degrees C.

Additionally, the substrate that has undergone the second step may be subjected to cleaning processing by use of Broensted acid.

In this manner, the present invention can provide a recycled substrate produced by the above-described method for producing a recycled substrate. Further, the present invention can provide a nitride semiconductor element and a lamp by use of the recycled substrate.

### Advantageous Effects of Invention

According to the present invention, it is possible to eliminate a laminated semiconductor layer from a laminated semiconductor wafer while suppressing damage to the substrate.

### BRIEF DESCRIPTION OF DRAWINGS

FIG. 1 is an exemplary diagram showing a flow of a method for producing a recycled substrate according to the exemplary embodiment;

FIG. 2 is an exemplary diagram showing a configuration of the laminated semiconductor wafer;

FIG. 3 is an exemplary diagram for illustrating the overall configuration of a heating apparatus;

FIG. 4 is an exemplary diagram for illustrating the eliminating step; and

FIG. 5 is an exemplary graph for illustrating the example.

### DESCRIPTION OF EMBODIMENTS

An exemplary embodiment of the present invention will be described below in detail with reference to the accompanying drawings.

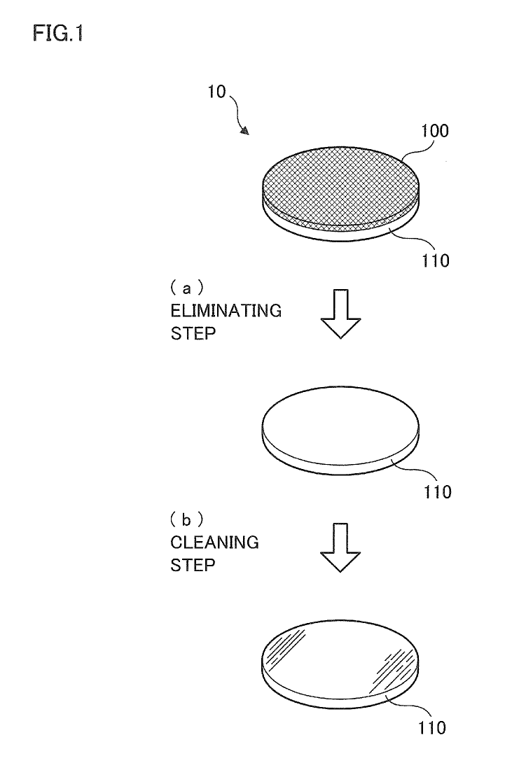

FIG. 1 is an exemplary diagram showing a flow of a method for producing a recycled substrate according to the present exemplary embodiment.

As shown in (a) of FIG. 1, a laminated semiconductor wafer 10 to be subjected to recycling processing of the present exemplary embodiment includes: a substrate 110 and a laminated semiconductor layer 100 formed on the substrate 110. Here, “recycling” refers to removing the laminated semiconductor layer 100 from the laminated semiconductor wafer 10 and making the substrate 110 reusable. In the present exemplary embodiment, the laminated semiconductor layer 100 is removed to such an extent that a new laminated semiconductor layer 100 can be favorably formed on the remaining substrate 110, for example.

As shown in (a) and (b) of FIG. 1, the method for producing a recycled substrate to which the present exemplary embodiment is applied includes “an eliminating step,” and preferably further includes “a cleaning step.” In the eliminating step shown in (a) of FIG. 1, the laminated semiconductor wafer 10 is subjected to heating processing, thereby to eliminate the laminated semiconductor layer 100. Additionally, in the cleaning step shown in (b) of FIG. 1, the substrate 110 obtained by eliminating the laminated semiconductor layer 100 in the eliminating step is cleaned by use of a cleaning agent.

Note that, for a substrate subjected to embossing on at least one surface thereof, the method for producing a recycled substrate to which the present exemplary embodiment is applied may further include a step of grinding and/or polishing after the above-mentioned “eliminating step” and “cleaning step.”

### <Configuration of Laminated Semiconductor Wafer>

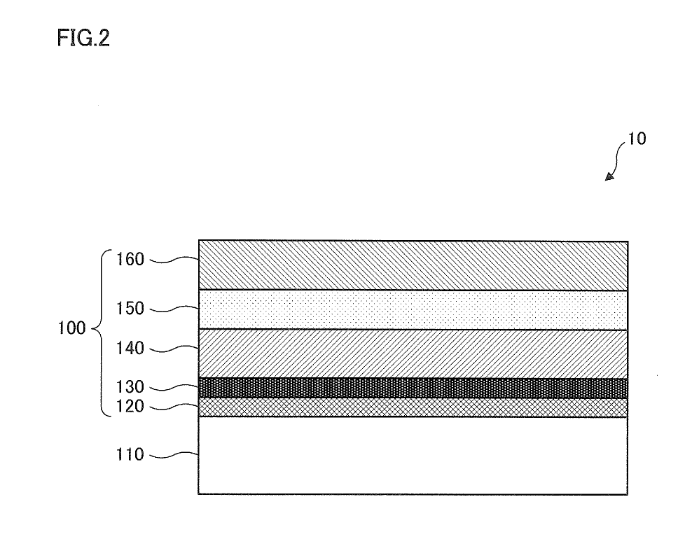

FIG. 2 is an exemplary diagram showing a configuration of the laminated semiconductor wafer 10.

As a compound semiconductor composing the laminated semiconductor wafer 10, a III-V compound semiconductor is preferable, and a group III nitride compound semiconductor is particularly preferable. In the following, a description is given by taking a laminated semiconductor wafer 10 having a group III nitride compound semiconductor as a specific example. Note that the laminated semiconductor wafer 10 shown in FIG. 2 serves as a starting material to produce a blue light emitting chip that emits blue light, for example, and further a light emitting device (lamp) that uses the blue light emitting chip.

As described above, the laminated semiconductor wafer 10 includes the substrate 110 and the laminated semiconductor layer 100. In the present invention, a wafer that includes a substrate 110 and at least one or more semiconductor layers and preferably two or more semiconductor layers is used as the laminated semiconductor wafer 10. As shown in FIG. 2, the laminated semiconductor layer 100 of the present exemplary embodiment includes an intermediate layer 120 formed on the substrate 110, and a base layer 130, an n-type semiconductor layer 140, a light emitting layer 150 and a p-type semiconductor layer 160 that are sequentially laminated on the intermediate layer 120.

On the substrate 110, group III nitride compound semiconductor crystals are epitaxially grown. Sapphire and silicon carbide (SiC) are mainly used as a material composing the substrate 110. Note that a sapphire substrate is used for the substrate 110 of the present exemplary embodiment.

The substrate 110 of the present exemplary embodiment has a diameter of 4 inches (about 100 mm) and a thickness of 0.5 mm to 1.5 mm. Note that a substrate having a diameter of 2 inches (a thickness of 0.2 mm to 0.7 mm), a substrate having a diameter of 6 inches (a thickness of 0.7 mm to 1.7 mm) or the like may be used as the substrate 110.

In general, a buffer layer composed of AlGaN or GaN is laminated on the substrate 110. The n-type semiconductor layer 140 is formed of GaN, AlGaN, GaInN and the like. The light emitting layer 150 employs, for example, a single quantum well structure or a multiple quantum well structure in which GaN and GaInN are alternatively laminated. The p-type semiconductor layer 160 is formed of GaN and AlGaN.

In this manner, the laminated semiconductor layer 100 of the present exemplary embodiment is formed of group III nitride compound semiconductor layers. The main component of the laminated semiconductor layer 100 of the present exemplary embodiment (the material occupying the largest amount in the laminated semiconductor layer 100) is GaN (gallium nitride).

### <Configuration of Heating Apparatus>

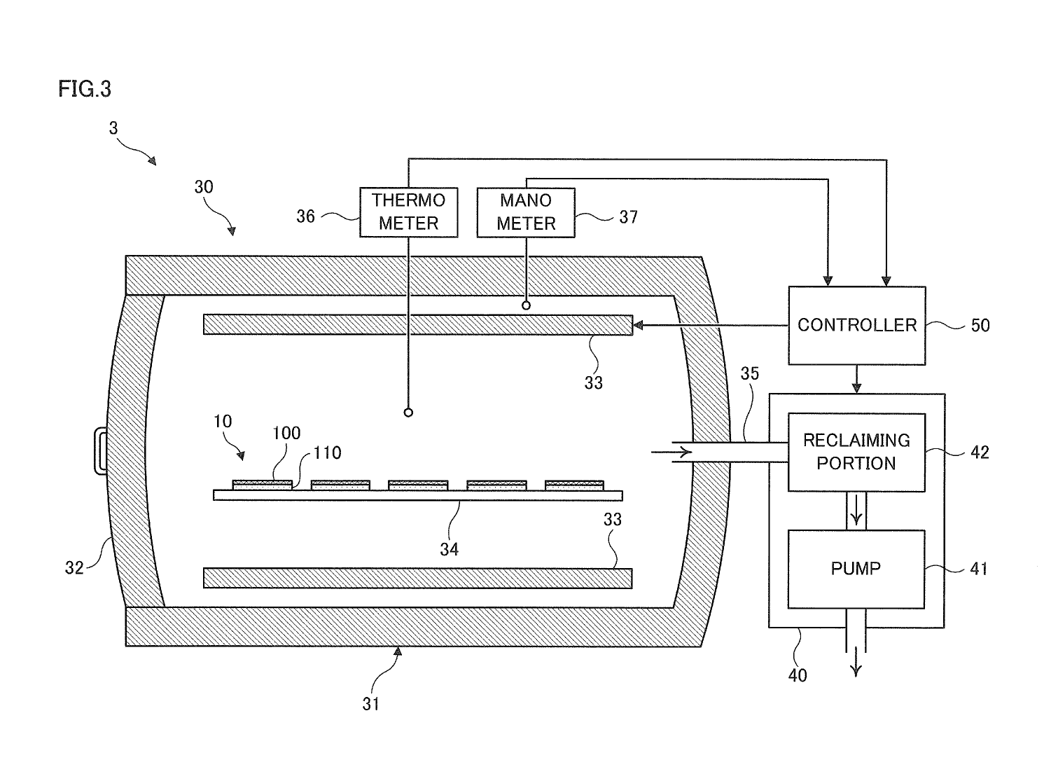

FIG. 3 is an exemplary diagram for illustrating the overall configuration of a heating apparatus 3.

The heating apparatus 3 is an apparatus used in “the eliminating step.” As shown in FIG. 3, the heating apparatus 3 of the present exemplary embodiment includes: a heating furnace 30; an exhaust device 40 for exhausting an atmospheric gas in the heating furnace 30; and a controller 50 for controlling operations of the heating furnace 30 and the exhaust device 40.

### (Configuration of Heating Furnace 30)

The heating furnace 30 has a chamber 31, a heater 33, a stage 34, a thermometer 36 and a manometer 37. The chamber 31 is a container that is capable of forming an enclosed space. The chamber 31 of the present exemplary embodiment is made of stainless steel. The laminated semiconductor wafer 10, which is a heating target of the present exemplary embodiment, is put into the chamber 31. Then, the laminated semiconductor wafer 10 is heated. The chamber 31 is also provided with an opening and closing door 32, as shown in FIG. 3. When the laminated semiconductor wafer 10 is put in or taken out, the opening and closing door 32 is opened to leave the chamber 31 open. Meanwhile, on the occasion of heating, the opening and closing door 32 is closed to make the inside of the chamber 31 an enclosed space.

In the present exemplary embodiment, the laminated semiconductor wafer 10 is heated with the inside of the chamber 31 being decompressed as will be described later. Accordingly, the chamber 31 of the present exemplary embodiment has enough strength to withstand reduced pressure. Additionally, the chamber 31 is equipped with a duct 35 for exhausting the atmospheric gas in the chamber 31, on the opposite side of the opening and closing door 32, as shown in FIG. 3. The duct 35 connects the space of the chamber 31 to that of the exhaust device 40. When the inside of the chamber 31 is decompressed, the exhaust device 40 is used to exhaust the atmospheric gas in the chamber 31 through the duct 35.

The heater 33 is a heat source for heating the laminated semiconductor wafer 10, which is a heating target of the present exemplary embodiment. In the present exemplary embodiment, the heater 33 is used to make the atmosphere temperature in the chamber 31 be a predetermined temperature, while the laminated semiconductor wafer 10 is put in the atmosphere to heat the laminated semiconductor wafer 10 to the predetermined temperature.

A carbon heater may be used for the heater 33 of the present exemplary embodiment. The heater 33 is attached to inner walls of the chamber 31 so as to enclose the stage 34 on which the laminated semiconductor wafer 10 is placed. The heater 33 radiates infrared rays and heat by being supplied with electric power. In the present exemplary embodiment, a carbon heater, which is a heat source causing no combustion, is used as the heater 33, so that the inside of the chamber 31 is not fouled by the heater 33. The heater 33 is controlled by the controller 50. Specifically, the controller 50 adjusts the amount of electric power supplied to the heater 33, thereby to control a heating temperature for the laminated semiconductor wafer 10.

The stage 34 is a stage on which the laminated semiconductor wafer 10, which is a heating target of the present exemplary embodiment, is placed. Molybdenum, carbon or the like may be used for the material of the stage 34. Note that plural laminated semiconductor wafers 10 can be placed on the stage 34 of the present exemplary embodiment.

The thermometer 36 is what measures the temperature of the inside of the chamber 31. The thermometer 36 of the present exemplary embodiment is a temperature sensor using a thermocouple. The temperature measured by the thermometer 36 is sent to the controller 50. The controller 50 adjusts the amount of electric power supplied to the above-mentioned heater 33 on the basis of the temperature obtained by the thermometer 36 and a preset temperature, thereby to control the heating temperature of the heater 33. Note that it is preferable to provide the heating apparatus 3 with a temperature sensing device such as a radiation thermometer, and to detect the temperature of the laminated semiconductor wafer 10 directly, thereby to control the temperature.

The manometer 37 is what measures the pressure of the inside of the chamber 31. The pressure in the chamber 31 measured by the manometer 37 is sent to the controller 50. The controller 50 adjusts the exhaust flow of the pump 41 in the exhaust device 40 to be described later on the basis of the pressure obtained by the manometer 37 and a preset pressure, thereby to control the pressure in the chamber 31.

### (Configuration of Exhaust Device 40)

The exhaust device 40 includes the pump 41 and a reclaiming portion 42. The pump 41 exhausts the atmospheric gas in the chamber 31. The pump 41 exhausts the atmospheric gas in the chamber 31 through the reclaiming portion 42 and the duct 35, as shown in FIG. 3. Note that various types of pumps, such as a wet pump and a dry pump, may be used as the pump 41. In the present exemplary embodiment, a turbo molecular pump, which exhausts gases by rotating turbine blades, is used as the pump 41.

The reclaiming portion 42 reclaims a particular substance from the atmospheric gas exhausted by the pump 41. The reclaiming portion 42 is arranged between the pump 41 and the chamber 31, as shown in FIG. 3. In the present exemplary embodiment, the group III nitride compound semiconductor to be eliminated is mainly composed of GaN. The reclaiming portion 42 reclaims Ga among Ga and N that are eliminated from the laminated semiconductor wafer 10 in the chamber 31 and are decomposed. For example, a filter to adsorb Ga may be used as the reclaiming portion 42.

The controller 50 receives a setting of the heating temperature for the laminated semiconductor wafer 10 in the eliminating step, a setting of the pressure in the chamber 31, and the like, through an operation panel (not shown). The controller 50 is connected to the thermometer 36 and the manometer 37. The controller 50 controls the heater 33 on the basis of the received setting value of the heating temperature and the temperature in the chamber 31 obtained from the thermometer 36 so that the temperature of the atmosphere in the chamber 31 is equal to the received setting value of the heating temperature. Additionally, the controller 50 controls the pump 41 on the basis of the received setting value of the pressure and the pressure in the chamber 31 obtained from the manometer 37 so that the pressure in the chamber 31 is equal to the received setting value of the pressure.

### <Procedure for Producing Recycled Substrate>

Subsequently, a detailed description is given of a procedure (the eliminating step and the cleaning step) for producing a recycled substrate according to the present exemplary embodiment.

### “Eliminating Step”

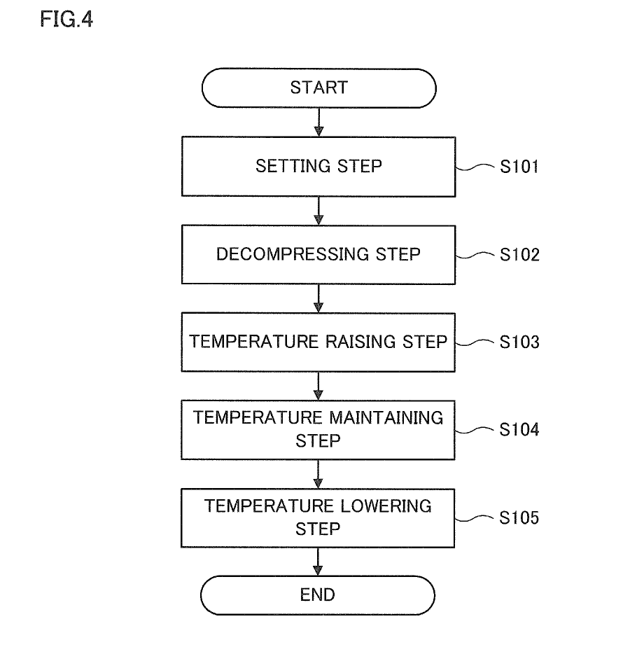

FIG. 4 is an exemplary diagram for illustrating the eliminating step. The eliminating step of the present exemplary embodiment aims to separate and eliminate the laminated semiconductor layer 100 from the substrate 110 by heating the laminated semiconductor wafer 10 to cause the laminated semiconductor layer 100 in the laminated semiconductor wafer 10 to sublime.

As shown in FIG. 4, the eliminating step of the present exemplary embodiment includes: a setting step (step 101) that is a step of setting the laminated semiconductor wafer 10 in the heating apparatus 3; a decompressing step (step 102) that is a step of decompressing the inside of the chamber 31 of the heating apparatus 3; and a temperature raising step (step 103) that is a step of raising the temperature of the laminated semiconductor wafer 10. Further, the eliminating step of the present exemplary embodiment includes: a temperature maintaining step (step 104) of maintaining the laminated semiconductor wafer 10 at a predetermined temperature for a given length of time; and a temperature lowering step (step 105) of lowering the temperature of the substrate 110 left by elimination of the laminated semiconductor layer 100 from the laminated semiconductor wafer 10.

Note that, in the eliminating step, the laminated semiconductor wafer 10 may be heated in a reduction atmosphere where the atmosphere condition in the chamber 31 is H₂. Also in this case, the maintained temperature is set at a temperature above the sublimation point of the laminated semiconductor layer 100 and under the melting point of the substrate 110. In this manner, decomposition of the group III nitride compound semiconductor composing the laminated semiconductor layer 100 may be further facilitated, and elimination of the laminated semiconductor layer 100 from the laminated semiconductor wafer 10 may be made easier.

### (Setting Step)

The laminated semiconductor wafer 10 is placed on the stage 34 of the heating apparatus 3 so that the laminated semiconductor layer 100 side of the laminated semiconductor wafer 10 faces upward (the side opposite to the stage 34). In the present exemplary embodiment, plural laminated semiconductor wafers 10 are placed on the stage 34, as shown in FIG. 3.

### (Decompressing Step)

Upon completion of setting of the laminated semiconductor wafer 10, the opening and closing door 32 of the chamber 31 is closed. Then, the pump 41 is used to exhaust the atmospheric gas in the chamber 31, thereby decompressing the inside of the chamber 31 below the atmospheric pressure.

Note that the decompression of the inside of the chamber 31 continues even in the temperature raising step and the temperature maintaining step to be described later. In this manner, in the present exemplary embodiment, the inside of the chamber 31 is decompressed to facilitate sublimation of the laminated semiconductor layer 100 in the laminated semiconductor wafer 10 and to make elimination of the laminated semiconductor layer 100 easier. It is preferable that the pressure in the chamber 31 be set at 5×10⁻² Torr (6.7 Pa) or less while the laminated semiconductor layer 100 is eliminated in the temperature raising step and the temperature maintaining step.

### (Temperature Raising Step)

In the temperature raising step, the heater 33 is used to heat the atmosphere in the chamber 31, thereby to raise the temperature of the laminated semiconductor wafer 10. In the present exemplary embodiment, the temperature of the laminated semiconductor wafer 10 is raised up to the maintained temperature in the temperature maintaining step to be described later. The temperature raising rate in the temperature raising step is preferably set at about 2 degrees C./min to about 30 degrees C./min. Note that the temperature raising step may be divided into plural stages, such as time periods that have different temperature raising rates, to raise the temperature in the chamber 31 (the laminated semiconductor wafer 10).

As described above, the decompression of the inside of the chamber 31 by use of the exhaust device 40 continues even in the temperature raising step. That is, the laminated semiconductor wafer 10 is heated while the pressure in the chamber 31 is decreased below the atmospheric pressure in the temperature raising step.

### (Temperature Maintaining Step)

The temperature maintaining step is a step of maintaining the laminated semiconductor wafer 10 at a predetermined temperature for a given length of time. Note that, in the present exemplary embodiment, the temperature maintained in the temperature maintaining step is referred to as maintained temperature. The maintained temperature is preferably between 800 degrees C. and 2000 degrees C. More preferably, the maintained temperature is between 1000 degrees C. and 1600 degrees C. In the present exemplary embodiment, the temperature of the atmospheric gas in the chamber 31 is heated up to the maintained temperature, thereby to make the temperature of the laminated semiconductor wafer 10 be the above-mentioned maintained temperature.

The decompression of the inside of the chamber 31 by use of the exhaust device 40 continues even in the temperature maintaining step. That is, the laminated semiconductor wafer 10 is heated by use of the above-mentioned maintained temperature while the pressure in the chamber is decreased below the atmospheric pressure in the temperature maintaining step of the present exemplary embodiment.

As for the laminated semiconductor wafer 10 of the present exemplary embodiment, for example, the laminated semiconductor layer 100 is a group III nitride compound semiconductor layer while the substrate 110 is a sapphire substrate. In particular, the laminated semiconductor layer 100 is mainly composed of GaN. The eliminating step aims to eliminate the laminated semiconductor layer 100 from the substrate 110 by heating the laminated semiconductor wafer 10 to cause the laminated semiconductor layer 100 to sublime. Accordingly, in the present exemplary embodiment, the lower bound of the maintained temperature is 800 degrees C. or more that is a temperature (the sublimation point) at which GaN starts subliming. On the other hand, the upper limit of the maintained temperature is less than 2040 degrees C. that is a temperature (the melting point) at which sapphire starts melting. In this manner, if the substrate 110 is a sapphire substrate, the maintained temperature is preferably between 800 degrees C. and 2000 degrees C., further preferably between 800 degrees C. and 1800 degrees C., and further preferably between 1000 degrees C. and 1600 degrees C.

Meanwhile, the maintaining time in the temperature maintaining step is specified on the basis of time required in order that almost all the laminated semiconductor layer 100 of the laminated semiconductor wafer 10 sublimes and is eliminated from the substrate 110 while the temperature of the laminated semiconductor wafer 10 is maintained at the maintained temperature. Note that, even in the temperature raising step, the laminated semiconductor layer 100 may sublime in some cases depending on the heating temperature. In such a case, the maintained temperature of the temperature maintaining step may be specified by taking account of the heating time of the temperature raising step.

### (Temperature Lowering Step)

Then, after a lapse of the maintaining time having been set, the substrate 110 left by elimination of the laminated semiconductor layer 100 is cooled. If the substrate 110 is rapidly cooled, dislocation may occur in the substrate 110 due to thermal shock. The temperature lowering rate in the temperature lowering step is preferably set at about 5 degrees C./min to about 10 degrees C./min. The temperature lowering step may be divided into plural stages, such as time periods that have different temperature lowering rates, to lower the temperature of the substrate 110 (the atmospheric gas). Further, in the temperature lowering step, an inert gas such as N₂, for example, may be introduced into the chamber 31 to facilitate cooling of the substrate 110.

### “Cleaning Step”

In the cleaning step, the substrate 110 left by elimination of the laminated semiconductor layer 100 is first immersed in Broensted acid or heated Broensted acid. For example, the above-mentioned substrate 110 is immersed for about 1 minute in heated phosphoric acid (about 190 degrees C.), which is an example of Broensted acid. After that, the substrate 110 is immersed in pure water in order to wash away the phosphoric acid adhering to the substrate 110. In the present exemplary embodiment, for example, tiny foreign particles adhering to the substrate 110 are removed through the cleaning step.

Additionally, for a substrate subjected to embossing on at least one surface thereof, the method for producing a recycled substrate according to the present invention includes the above-described “eliminating step” and preferably “the cleaning step,” and may further include a step of polishing the substrate, although a mention thereof is omitted in FIG. 4. Note that if the polishing step is included, it is preferable that the amount of polishing be 10 gm or more. An example of a substrate subjected to embossing on at least one surface thereof is a substrate disclosed in Japanese Patent Application Laid-Open Publication No. 2009-123717, for example, the substrate having plural convex portions formed on the (0001) C-plane thereof, the convex portions being formed of surfaces nonparallel to the C-plane. In the publication, a substrate having the following convex portions is used: each of the convex portions is 0.05 to 5 gm in width of a base portion thereof and 0.05 to 5 gm in height; the height is not less than ¼ of the width of the base portion; and the distance between adjacent convex portions is 0.5 to 5 times the width of the base portion.

Furthermore, if the convex portions on the substrate has a large structure, it is preferable to incorporate a grinding step before the polishing step, and to remove a damaged layer of a surface generated in the grinding step by the order of several tens of gm in a lapping step, and then to polish more than 10 gm in order to eliminate a damaged layer caused by lapping. The type of the grinding material or the polishing material is not particularly limited, but a commercially available slurry grinding or polishing material may be used. A known green carbide (GC) abrasive grain, diamond abrasive grain and the like are used for the lapping material, while cerium oxide, colloidal silica and the like are used for the polishing material.

### EXAMPLE

Hereinafter, a specific description of the present invention is given on the basis of an example. However, the present invention is not limited only to the example.

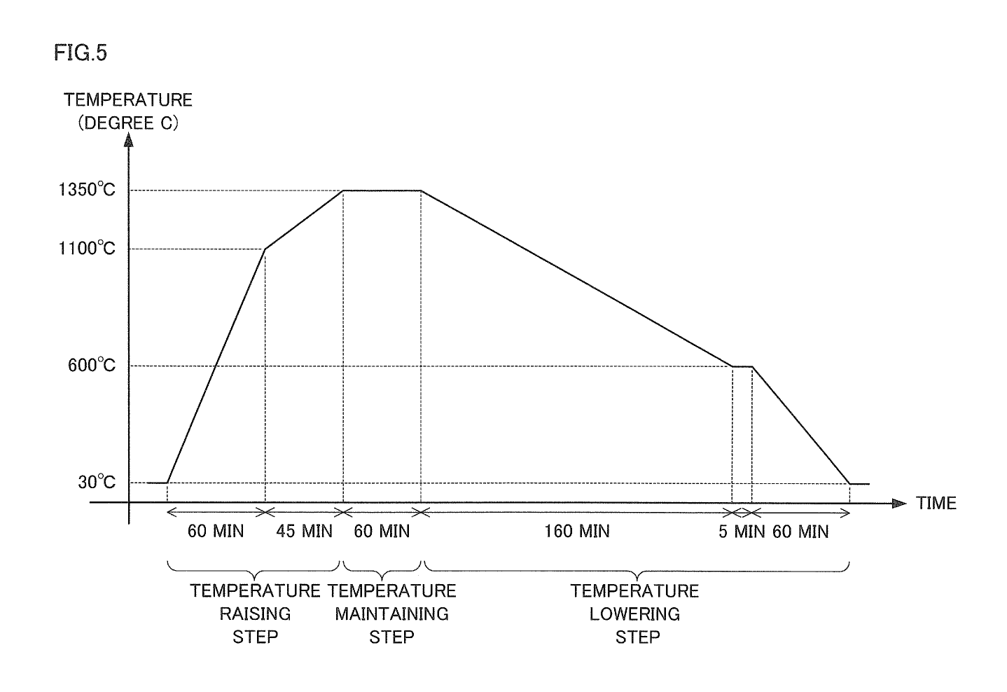

FIG. 5 is an exemplary graph for illustrating the example. Note that a laminated semiconductor wafer 10 that is a target in the present example is a wafer obtained by laminating layers composed of plural GaN-based compounds on a sapphire substrate.

First, plural laminated semiconductor wafers 10 are arranged on the stage 34 (see FIG. 3) of the heating apparatus 3 (the setting step). Subsequently, the exhaust device 40 is used to exhaust the atmospheric gas in the chamber 31, and to decompress until the pressure in the chamber 31 becomes 5×10⁻² Torr (about 6.7 Pa) or less (the decompressing step).

Then, the heater 33 is used to raise the temperature in the chamber 31 up to 1350 degrees C. (the temperature raising step). At this time, in the present example, the atmosphere temperature in the chamber 31 is raised through two divided stages. That is, as shown in FIG. 5, the temperature raising step is provided with: a first stage in which the temperature is raised from 30 degrees C., which is the initial temperature in the chamber 31, to 1100 degrees C.; and a second stage in which the temperature is raised from 1100 degrees C. to 1350 degrees C. In the first stage, the temperature raising rate is set at about 18 degrees C./min, and the temperature is raised for 60 minutes from 30 degrees C. to 1100 degrees C. Further, in the second stage, the temperature raising rate is set at about 5.5 degrees C./min, and the temperature is raised for 45 minutes from 1100 degrees C. to 1350 degrees C.

Now, consider a case in which the temperature raising rate is set higher to raise the temperature rapidly up to 1350 degrees C., for example. As described above, in the present exemplary embodiment, the laminated semiconductor wafers 10 are heated with the inside of the chamber 31 being decompressed. Setting the temperature raising rate too high increases the possibility that a large amount of the GaN-based compound sublimes in a short time period. Then, the pressure in the chamber 31 rapidly rises, which might result in a decrease in elimination efficiency.

Thus, in the present example, 1100 degrees C. is regarded as a target temperature, for example, and the temperature raising rate is set relatively high (at 18 degrees C./min in the present exemplary embodiment) to a certain extent up to 1100 degrees C., so that the time required for all the steps is reduced. On the other hand, in the stage where sublimation prominently occurs at temperatures over 1100 degrees C., for example, the temperature raising rate is set relatively low (at 5.5 degrees C./min in the present exemplary embodiment).

In the present example, measurement of the pressure at a stage when the temperature in the chamber 31 arrives at 1100 degrees C. gives 9×10⁻²Torr (about 20.0 Pa). This is an increased value as compared with the initial pressure in the chamber 31 (5×10⁻² Torr (about 6.7 Pa)). Thus, it can be seen that GaN in the laminated semiconductor wafers 10 sublimes at the stage when the temperature in the chamber 31 arrives at 1100 degrees C.

Then, after the temperature raising step, the heater 33 is used to maintain the temperature of the atmosphere in the chamber 31 at 1350 degrees C. (the temperature maintaining step). The temperature maintaining step continues for a time period enough to eliminate the laminated semiconductor layer 100 of each laminated semiconductor wafer 10. In the present exemplary embodiment, the maintaining time is set at 60 minutes.

Note that measurement of the pressure in the chamber 31 soon after the transition to the temperature maintaining step gives 5×10⁻² Torr (about 6.7 Pa). Thus, in the present example, it is conceivable that most of GaN is eliminated in the temperature raising step, and that the whole GaN is eliminated in the temperature maintaining step.

In the temperature raising step and the temperature maintaining step of the present exemplary embodiment, sublimed GaN separates into Ga and N₂ in the chamber 31. The separated Ga and N₂ move to the exhaust device 40, which has a lower pressure. Then, in the exhaust device 40, Ga is reclaimed by the reclaiming portion 42, while N₂ is emitted to the outside.

After the completion of the temperature maintaining step, heating by the heater 33 is stopped. Then, the temperature of the substrate 110 is gradually decreased (the temperature lowering step). As shown in FIG. 5, in the temperature lowering step of the present example, the temperature of the atmosphere is first decreased by natural cooling from 1350 degrees C. to 600 degrees C. Then, at a stage when the temperature of the atmosphere has been decreased to 600 degrees C., an inert gas such as N₂ and Ar (argon) is introduced into the chamber 31, thereby to enhance the cooling efficiency of the substrate 110. In this manner, after the temperature of the substrate 110 has been decreased to a certain extent, like 600 degrees C., for example, the temperature lowering rate is set higher to reduce the time required for the step. In the present exemplary embodiment, as shown in FIG. 5, the temperature of the atmosphere is decreased for 160 minutes from 1350 degrees C. to 600 degrees C., and further for 60 minutes from 600 degrees C. to 30 degrees C.

Then, the laminated semiconductor layer 100 (GaN-based compound) is removed from each laminated semiconductor wafer 10. Thus, the substrates 110 (recycled substrates) left by elimination of the laminated semiconductor layers 100 have been obtained.

As has been described above, in the present exemplary embodiment, the laminated semiconductor layer 100 is removed from the laminated semiconductor wafer 10 by heating the laminated semiconductor wafer 10.

The eliminating step of the present exemplary embodiment achieves the elimination of the laminated semiconductor layer 100 by use of heating, which is a noncontact method, without performing any mechanical processing such as, for example, injecting a blasting material into the laminated semiconductor wafer 10 and grinding the laminated semiconductor wafer 10 by use of a grindstone. Accordingly, it is possible to produce a recycled substrate without damaging the substrate 110.

If an attempt is made to eliminate the laminated semiconductor layer 100 from the laminated semiconductor wafer 10 by grinding, for example, it is necessary to adjust the amount of grinding depending on the film thickness of the laminated semiconductor layer 100 so that the substrate 110 is not largely ground. In contrast, in the present exemplary embodiment, it is possible to perform processing of substrate recycling collectively on plural laminated semiconductor wafers 10 having different film thicknesses and the like, without individually adjusting conditions. In this manner, the method for producing a recycled substrate according to the present exemplary embodiment is suitable for a case where a large number of recycled substrates are produced, for example.

Furthermore, according to the present invention, a wafer having electrodes formed on the laminated semiconductor layer 100 can be recycled.

### REFERENCE SIGNS LIST

3 . . . heating apparatus
10 . . . laminated semiconductor wafer
100 . . . laminated semiconductor layer
110 . . . substrate

1. A method for producing a recycled substrate by removing a laminated semiconductor layer from a laminated semiconductor wafer that has the laminated semiconductor layer formed on a substrate, the method comprising:
a first step of setting, in a heating apparatus, the laminated semiconductor wafer that has the laminated semiconductor layer formed on the substrate; and
a second step of heating the laminated semiconductor wafer to a temperature above the sublimation point of the laminated semiconductor layer and under the melting point of the substrate.

2. The method for producing a recycled substrate according to claim 1, wherein, in the second step, the laminated semiconductor wafer is heated by decreasing pressure in the heating apparatus below atmospheric pressure.

3. The method for producing a recycled substrate according to claim 1, wherein, in the second step, the temperature is maintained while the laminated semiconductor layer is eliminated from the laminated semiconductor wafer.

4. The method for producing a recycled substrate according to claim 1, wherein the laminated semiconductor layer of the laminated semiconductor wafer includes a group III nitride compound semiconductor.

5. The method for producing a recycled substrate according to claim 1, wherein the substrate of the laminated semiconductor wafer is a sapphire substrate.

6. The method for producing a recycled substrate according to claim 5, wherein, in the second step, the laminated semiconductor wafer is heated to a temperature between 800 degrees C. and 2000 degrees C.

7. The method for producing a recycled substrate according to claim 1, wherein the substrate that has undergone the second step is subjected to cleaning processing by use of Broensted acid.

8. A recycled substrate produced by the method for producing a recycled substrate according to claim 1.

9. A nitride semiconductor element and a lamp that are produced by use of the recycled substrate according to claim 8.
